(19) United States
(12) Patent Application Publication
(10) Pub. No.: US 2018/0323061 A1
(43) Pub. Date: Nov. 8, 2018

(54) Self-Aligned Triple Patterning Process Utilizing Organic Spacers

(71) Applicant: Tokyo Electron Limited, Tokyo (JP)

(72) Inventors: Angelique D. Raley, Albany, NY (US); Sophie Thibaut, Albany, NY (US); Richard Farrell, Albany, NY (US)

(21) Appl. No.: 15/970,168

(22) Filed: May 3, 2018

Related U.S. Application Data
(60) Provisional application No. 62/500,588, filed on May 3, 2017.
(60) Provisional application No. 62/527,733, filed on Jun. 30, 2017.
(60) Provisional application No. 62/568,046, filed on Oct. 4, 2017.

(51) Int. Cl. H01L 21/027; H01L 21/311; H01L 21/02; H01L 21/033

(52) U.S. Cl. CPC H01L 21/0271; H01L 21/31138; H01L 21/31144; H01L 21/0228; H01L 21/02274; H01L 21/02282; H01L 21/0332; H01L 21/02118

(57) ABSTRACT

A method to implement self-aligned triple patterning techniques for the processing of substrates is provided. In one embodiment, a self-aligned triple processing technique utilizing an organic spacer is provided. The organic spacer may be formed utilizing any of a wide range of techniques including, but not limited to, plasma deposition and spin on deposition. In one embodiment, the organic spacer may be formed via a cyclic deposition etch process. In one embodiment, the self-aligned triple patterning technique may be utilized to form patterned structures on a substrate at pitches of 26 nm or less.

### RELATED APPLICATIONS

This application claims priority to the following co-pending provisional applications: U.S. Provisional Patent Application Ser. No. 62/500,588, filed May 3, 2017, and entitled “LOW COST SELF-ALIGNED TRIPLE PATTERNING SCHEME UTILIZING ORGANIC SPACER MATERIALS” and U.S. Provisional Patent Application Ser. No. 62/527,733, filed Jun. 30, 2017, and entitled “LOW COST SELF-ALIGNED TRIPLE PATTERNING SCHEME UTILIZING ORGANIC SPACER MATERIALS” and U.S. Provisional Patent Application Ser. No. 62/568,046, filed Oct. 4, 2017, and entitled “SELF-ALIGNED TRIPLE PATTERNING PROCESS UTILIZING ORGANIC SPACERS” which are hereby incorporated by reference in their entirety.

### BACKGROUND

The present disclosure relates to the processing of substrates, such as for example, semiconductor substrates. In particular, it provides a novel method to pattern substrates utilizing triple patterning techniques.

As geometries in substrate processing continue to shrink, the technical challenges to forming structures on substrates via photolithography techniques increase. As requirements for sub 80 nm pitch structures arose, one technique for achieving suitable photolithography for such pitches involves multiple patterning techniques to provide for pitch splitting. Such multiple patterning techniques have included self-aligned double patterning, self-aligned triple patterning and self-aligned quadruple patterning. These multiple patterning techniques may involve the utilization of sidewall spacers for defining structures at pitches that are less than the original photolithography pitch. Such techniques have allowed the extension of standard photolithography techniques without resort to extreme ultraviolet lithography.

For example, in self-aligned double patterning, sidewall spacers are utilized to double the structure density on the substrate surface. A mandrel structure may be formed on the substrate through known photolithography techniques. Sidewall spacers may then be formed adjacent the mandrel. Removal of the originally patterned mandrel leaves the two sidewall spacers, thus forming two structures for each mandrel. Similarly, self-aligned triple and quadruple patterning techniques are known. These techniques all require the use of one or more sacrificial layers and multiple etch steps, leading to increased costs and process complexities.

It would be desirable to provide a multiple patterning process integration technique that reduces the number of sacrificial layers utilized and can be implemented in a less complex process.

### SUMMARY

Described herein is an innovative method to implement self-aligned triple patterning techniques for the processing of substrates. In one embodiment, a self-aligned triple processing technique utilizing an organic spacer is provided. The organic spacer may be formed utilizing any of a wide range of techniques including, but not limited to, plasma deposition and spin on deposition. In one embodiment, the organic spacer may be formed via a cyclic deposition etch process. In one embodiment, the organic spacer may be placed between a mandrel and a second spacer. The organic spacer may be removed to allow the use of the mandrel and the second spacer for subsequent masking purposes.

In one embodiment, a method for processing a substrate is provided. The method may comprise providing a substrate with a plurality of first patterned structures and an underlying layer, the plurality of patterned structures having at least a first pitch. The method may further comprise forming an organic layer over the first patterned structures. The method may further comprise forming a plurality of organic spacers from said organic layer by performing a first spacer etch process, forming a second spacer layer over the organic spacers and forming a plurality of second spacers from said second spacer layer by performing a second spacer etch process. The method further comprises performing an organic spacer etch removal process, wherein after performing the organic spacer etch removal process, the plurality of first patterned structures and the plurality of second spacers together form a masking layer for generating a second pattern on the substrate. The second pattern may have a second pitch, the second pitch being less than the first pitch.

In another embodiment, a method for processing a substrate is provided. The method may comprise providing a substrate with a plurality of first patterned structures, forming a plurality of organic spacers adjacent to the plurality of first patterned structures, and forming a plurality of second spacers adjacent to the plurality of organic spacers. The method further includes removing the plurality of organic spacers after forming the plurality of second spacers, wherein after removing the plurality of organic spacers, the plurality of first patterned structures and the plurality of second spacers together form a masking layer which has masking layer structures having a pitch that is 26 nm or less.

In another embodiment, a method for performing a self-aligned triple patterning pitch splitting masking process is provided. The method may comprise providing a plurality of mandrels on a substrate, forming a plurality of organic spacers on the substrate, and forming a plurality of second spacers on the substrate, at least one organic spacer being located between at least one of the mandrels and at least one of the second spacers. The method further comprises performing an organic spacer etch removal process, the plurality of mandrels and the plurality of second spacers remaining on the substrate after the organic spacer etch removal process. The method further comprises after the organic spacer etch removal process, utilizing the plurality of mandrels and the plurality of second spacers as a self-aligned triple patterning pitch splitting mask for masking at least one layer of the substrate during at least one subsequent etch step.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1H illustrate exemplary process steps for one embodiment of a self-aligned triple patterning process utilizing organic spacers.

FIG. 2 illustrates an exemplary process flow for one embodiment of the substrate processing techniques disclosed herein.

FIG. 3 illustrates another exemplary process flow for one embodiment of the substrate processing techniques disclosed herein.

FIG. 4 illustrates another exemplary process flow for one embodiment of the substrate processing techniques disclosed herein.

### DETAILED DESCRIPTION

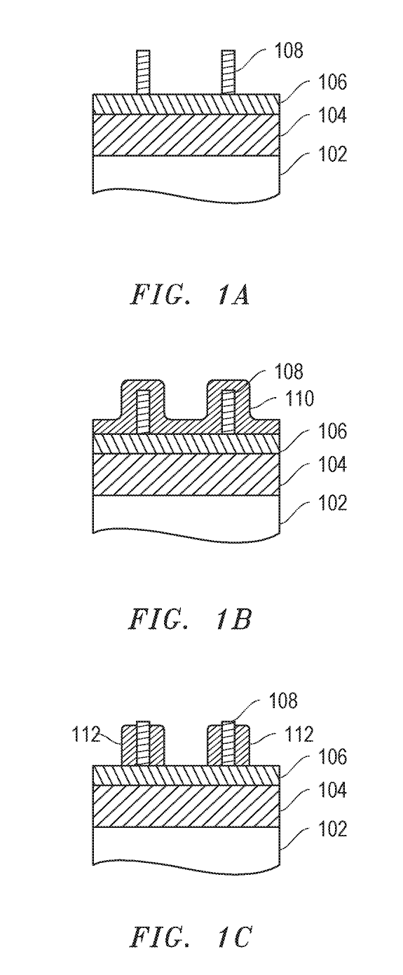

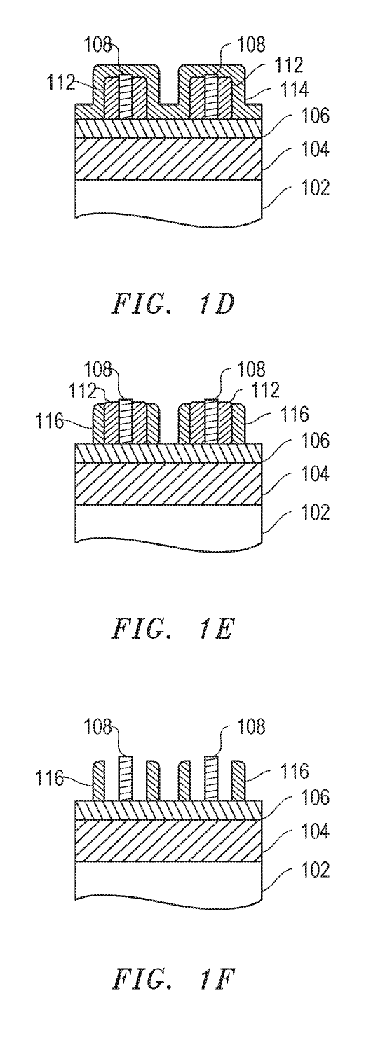

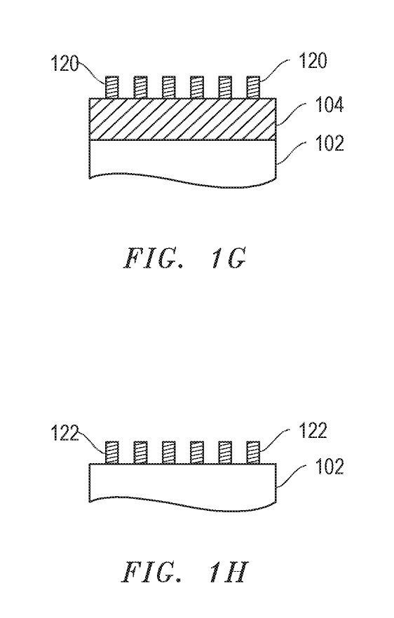

One embodiment of a process integration flow utilizing an organic spacer in a self-aligned triple patterning process is described with relation to FIGS. 1A-1H. As shown in FIG. 1A, mandrels 108 may be formed over a hard mask layer 106, etch stop layer 104, and substrate 102. Substrate 102 may be any substrate for which the use of patterned features is desirable. For example, in one embodiment, substrate 102 may be a semiconductor substrate having one or more semiconductor processing layers formed thereon. In one embodiment, the substrate 102 may be a substrate that has been subject to multiple semiconductor processing steps which yield a wide variety of structures and layers, all of which are known in the substrate processing art. In one embodiment, the self-aligned triple patterning techniques disclosed herein may be utilized at a back end of line (BEOL) processing step.

The techniques for forming a mandrel 108 in a multiple patterning process are well known in the art. As known, mandrel 108 may be patterned by any of a number of photolithography or other patterning techniques. In one embodiment, mandrel 108 may be formed through a process which utilizes photolithography techniques to pattern a resist layer over a mandrel layer. Any of a variety of photolithography techniques may be utilized. In one embodiment, the pitch of the patterned resist layer may be 80 nm or less. One or more intervening layers may be used as part of the photolithography process between the mandrel layer and the resist layer, include spin on glass (SOG) layers, spin on carbon (SOC) layers, antireflective coatings, etc., all as is known in the art.

After the patterning of the mandrel layer, the mandrels 108 remain as shown in FIG. 1A. In one embodiment, the mandrels 108 may be formed of a silicon nitride material. However, the mandrels 108 may be formed of any of a wide variety of other materials. As will be understood by reference to the rest of FIGS. 1A-1H as discussed below, one desirable property of the material utilized to form mandrels 108 is that the material is one in which etch selectivity to an organic layer may be obtained. For example, the mandrels 108 may be formed of any of a wide variety of materials, such as but not limited to, silicon nitride, silicon, silicon oxide, etc. or combinations thereof. As shown in FIG. 1, the mandrels 108 may be formed over a hard mask layer 106 and etch stop layer 104. The hard mask layer 106 and etch stop layer 104 may be formed of any of a wide variety of materials as is known in the art.

After the formation of mandrels 108, an organic spacer layer 110 may be provided over the mandrels 108 as shown in FIG. 1B. The organic spacer layer 110 may be comprised of any of a wide variety of organic materials to provide a conformal layer which may subsequently be used to form a spacer. As shown in FIG. 1C, the organic spacer layer 110 may be etched to leave organic spacers 112 on the sides of the mandrels 108. In one embodiment, the organic spacer layer 110 may be formed through a plasma deposition process which deposits organic material. In another embodiment, the organic spacer layer 110 may be formed through use of a spin on process to provide the organic material. In yet another embodiment, the organic material may be deposited through the use of an atomic layer deposition process. The organic layer 110 and corresponding organic spacers 112 may be comprised a wide variety of organic materials, such as, for example, but not limited to, hydrocarbons, CxHyNz materials include the family of pyrroles compounds (including, but not limited to, pyrrole and polypyrrole), carbon containing self-assembled monolayers, etc. For example the organic layer 110 may comprise, in some embodiments, C2H4, C3H6, C4H5N (pyrrole), CxHy, CxHyNz, etc. and combinations thereof.

In one embodiment, the process steps of FIGS. 1B and 1C may be combined in a plasma cyclic deposition etch process. As is known in the art, a cycle deposition etch process typically includes the use of series of deposition and etch processes. Thus, a partial deposition may be followed by a partial etch and then the partial deposition/etch process may be repeated until spacers, such as the spacers 112 as shown in FIG. 1C remain. In this manner, the formation of the organic spacers 112 may be accomplished in a single process step, as opposed to utilizing a separate deposition step and a separate etch step. Thus, process integration complexity and costs may be reduced.

After formation of the organic spacers 112, a second spacer layer 114 may be formed as shown in FIG. 1D. The second spacer layer 114 may be comprised of any of a wide variety of materials to provide a conformal layer. As shown in FIG. 1E, the second spacer layer 114 may then be etched to leave second spacers 116 on the sides of the organic spacers 112. As will be understood by reference to the discussion of FIG. 1F as discussed below, one desirable property of the material utilized to form second spacer layer 114 is that the material is one in which etch selectivity to an organic layer may be obtained. For example, the second spacer layer may be formed of silicon oxide. However, the second spacer layer may be any of a wide variety of other materials, provided the deposition temperature is low enough (<150 C) to prevent organic spacer deterioration, such as but not limited to, silicon oxide, aluminum oxide, titanium oxide, aluminum nitride, hafnium oxide, or combinations thereof. In one embodiment, a second spacer layer 114 that is comprised of silicon oxide may be etched by any of a wide variety of etch techniques, including but not limited to a directional fluorocarbon plasma etch, with a pressure comprised between 10 mT and 100 mT with preferred pressure ranging from 10 mT to 20 mT and a CxFy gas combined with a diluent such as helium or argon and some oxygen content to control polymerization.

After formation of the second spacers 116, as shown in FIG. 1F, the organic spacers 112 may then be selectively etched away. This leaves mandrels 108 and second spacers 116. The etch utilized to remove the organic spacers 112 may be any of a wide variety of etch techniques. A desirable property of the etch is that the etch provides selectivity between the organic material that forms the organic spacers 112 and the materials utilized to form the mandrels 108 and the second spacers 116. For example the etch may be chosen from any of a wide variety of etch techniques, including but not limited to H2/N2 plasma, oxygen plasma, CO2 plasma combined or not with a diluent gas such as He or Ar. As can be seen from FIG. 1F, patterned structures have now been formed on the substrate and the pitch of the patterned structures is substantially less than the original pitch of the mandrels 108. For example, a mandrel pitch of 80 nm or less may be reduced to a pitch of 26 nm or less.

The pattern formed by the mandrels 108 and the second spacers 116 may then be transferred to the hard mask layer 106 by subjecting the substrate 102 to an etch which etches the hard mask layer 106 selectively to the mandrels 108 and second spacers 116. The mandrels 108 and second spacers 116 may then be removed via an etch or strip step to leave patterned hard mask structures 120 as shown in FIG. 1G. The patterned hard mask structures 120 may then be utilized to form the patterned structures 122 shown in FIG. 1H via conventional mask and etch techniques as is known in the art. The patterned structures 122 may be formed within the etch stop layer and/or another layer of the substrate 102. For example in one embodiment, the patterned structure may be a structure that is part of the BEOL processing of a semiconductor substrate.

As described herein, use of a soft organic spacer is provided in a self-aligned tripling patterning process. The process advantageously provides pitch splitting geometries at 26 nm or less while requiring less sacrificial layers typically required in a self-aligned quadruple patterning scheme. Using the disclosed techniques provides complexity, number of steps, throughput, and/or costs benefits as compared to standard self-aligned quadruple patterning process flows or extreme ultraviolet lithography techniques. The use of an organic spacer material provides a process in which, at the fine geometries desired, sufficient conformity of the spacer deposition may be obtained for a material in which etch selectivity may be obtained between first spacer and both the mandrel and second spacer. In this manner, an organic spacer allows for the use of a self-aligned triple patterning process to be efficiently utilized for structure pitches of 26 nm or less.

As mentioned above, plasma deposition, atomic layer deposition and spin on methods may be utilized to form the organic layer 110. It will be recognized that other techniques may also be utilized. Though exemplary organic materials have been identified herein, it will be recognized that other organic materials may also be utilized. In one embodiment, the organic material may be a plasma deposited unsaturated hydrocarbon. In one embodiment, the organic material may be a plasma deposited pyrrole. In another embodiment, the organic material may be a carbon containing spin on deposited self-assembled monolayer. In one embodiment, organic layer 110 may have thicknesses in the range of 5 nm to 20 nm and more preferably 14 nm to 16 nm. Sidewall conformity of the organic layer 110 may be in the range of 90% to 100% and more preferably 100%. In one embodiment, the second spacer layer 114 may have thicknesses in the range of 5 nm to 20 nm and more preferably 14 nm to 16 nm. Sidewall conformity of the second spacer layer 114 may be in the range of 90% to 100% and more preferably 100%.

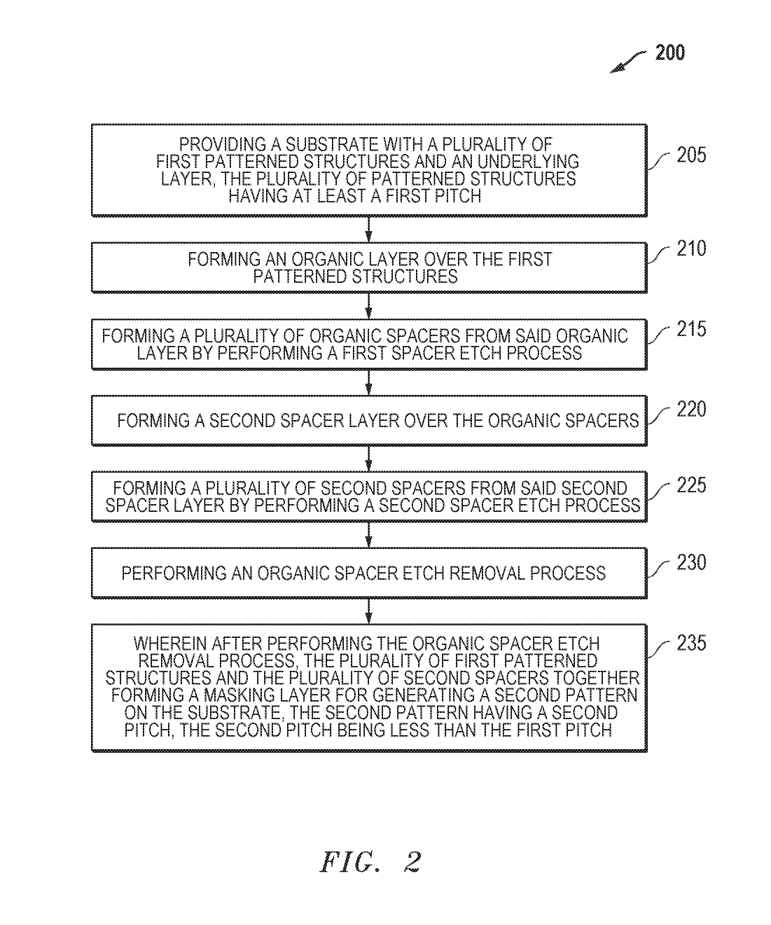

Exemplary process flows for utilizing the techniques described herein are provided in FIGS. 2-4. It will be recognized that these process flows are merely exemplary and the techniques described herein may be utilized in other manners. Further, it will be recognized that additional steps may be added to the exemplary process flows while still utilizing the advantageous benefits of the techniques disclosed herein. Additionally, it will be recognized by those skilled in the art that various steps of the process flows may be performed together or in combination, and thus, each step of the process flows is not limited to being a separate independent process step.

FIG. 2 illustrates a method 200 for processing a substrate. The method 200 may include a step 205 of providing a substrate with a plurality of first patterned structures and an underlying layer, the plurality of patterned structures having at least a first pitch. The method 200 includes forming an organic layer over the first patterned structures at step 210. The method 200 includes forming a plurality of organic spacers from said organic layer by performing a first spacer etch process at step 215. The method 200 includes forming a second spacer layer over the organic spacers at step 220. The method 200 includes forming a plurality of second spacers from said second spacer layer by performing a second spacer etch process at step 225. The method 200 includes performing an organic spacer etch removal process at step 230. As noted at step 235, after performing the organic spacer etch removal process, the plurality of first patterned structures and the plurality of second spacers together form a masking layer for generating a second pattern on the substrate, the second pattern having a second pitch, the second pitch being less than the first pitch.

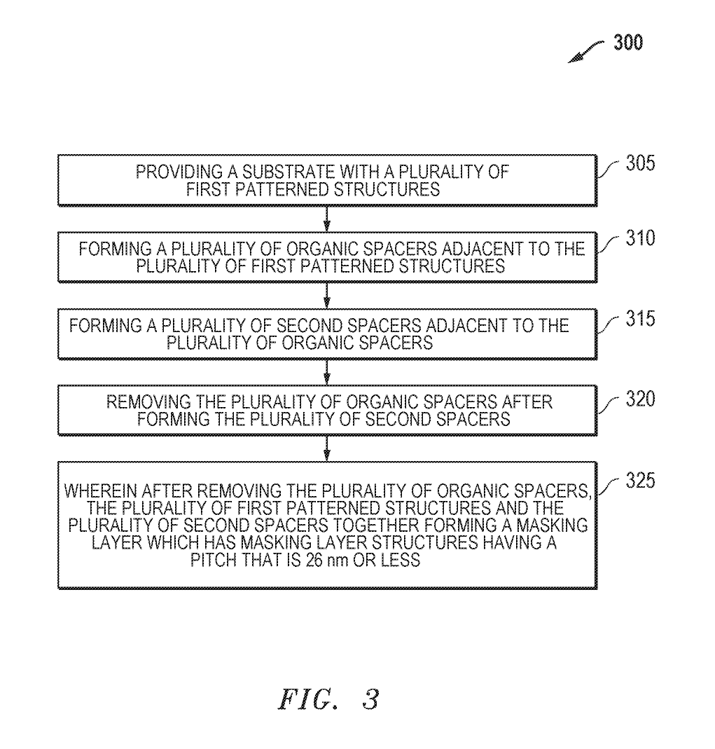

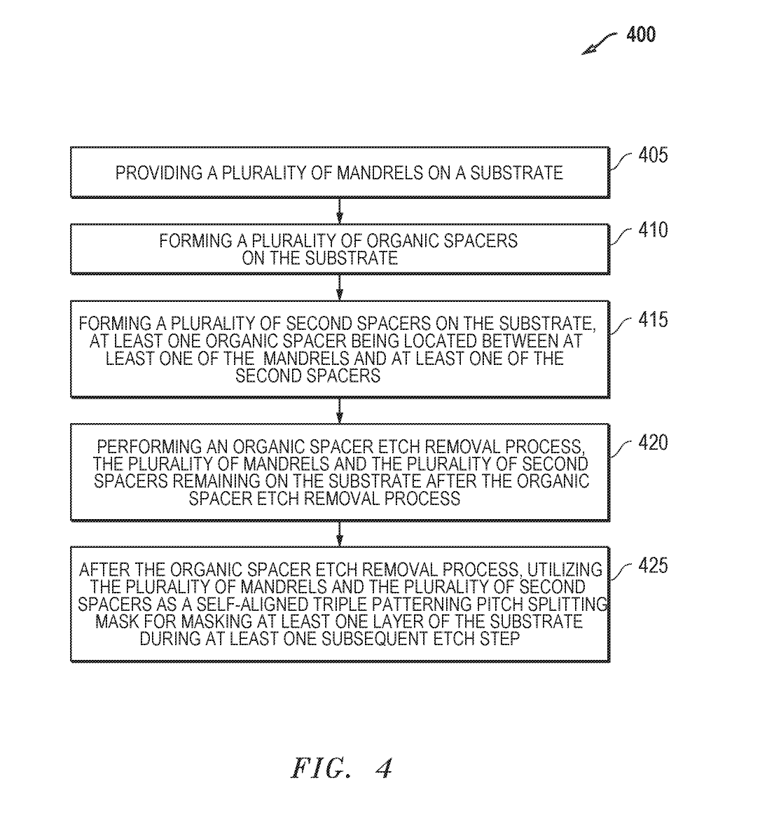

FIG. 3 illustrates a method 300 for processing a substrate. The method 300 may include a step 305 of providing a substrate with a plurality of first patterned structures. The method 300 includes forming a plurality of organic spacers adjacent to the plurality of first patterned structures at step 310. The method 300 includes forming a plurality of second spacers adjacent to the plurality of organic spacers at step 315. The method 300 includes, at step 320, removing the plurality of organic spacers after forming the plurality of second spacers. As noted at step 325, after removing the plurality of organic spacers, the plurality of first patterned structures and the plurality of second spacers together form a masking layer which has masking layer structures having a pitch that is 26 nm or less.

FIG. 4 illustrates a method 400 for performing a self-aligned triple patterning pitch splitting masking process. The method 400 may include a step 405 of providing a plurality of mandrels on a substrate. The method 400 includes forming a plurality of organic spacers on the substrate at step 410. The method 400 includes, at step 415, forming a plurality of second spacers on the substrate, at least one organic spacer being located between at least one of the mandrels and at least one of the second spacers. The method 400 includes, at step 420, performing an organic spacer etch removal process, the plurality of mandrels and the plurality of second spacers remaining on the substrate after the organic spacer etch removal process. After the organic spacer etch removal process, the method 400 includes, at step 425, utilizing the plurality of mandrels and the plurality of second spacers as a self-aligned triple patterning pitch splitting mask for masking at least one layer of the substrate during at least one subsequent etch step.

It will be recognized that many of the layers, and the materials that comprise the layers, that are described herein are merely exemplary. For example, the hard mask layer may be formed from aluminum oxide, titanium oxide, aluminum nitride, etc. Further, as an example, the etch stop layer may be formed from silicon nitride, silicon, silicon oxynitride, etc. However, other materials may be utilized and the concepts described herein may be implemented without even using such layers. It will be also recognized that the substrate 102 may be comprised of one or many layers. For example, the substrate 102 may be a semiconductor wafer that has many process layers formed on or in the semiconductor wafer. Thus, for example, the substrate 102 may be a semiconductor wafer at any process step in a semiconductor processing flow. For example, the substrate 102 may comprise a semiconductor wafer and all of its accompanying layers formed up to any particular process step. Further, it will be recognized that the various process layers and structures shown may be utilized with additional intervening process layers and coatings as would be understood by those in the art. Thus, for example, more or less materials may be utilized between the mandrels 108 and the substrate 102, additional layers or coatings may be utilized between the mandrels 108 and the organic layer 110, additional layers or coatings may be utilized between the organic spacers 112 and the second spacer layer 114, etc. Thus, it will be recognized that the use of a self-aligned triple patterning process in which an organic spacer is provided may be accomplished within a wide variety of process flows, all of which may advantageously benefit from the characteristics an organic spacer provides.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and describe herein and certain features of the inventions may be utilized independently of the use of other features, all as would be apparent to one skilled in the art after having the benefit of this description of the inventions.

What is claimed is:

1. A method for processing a substrate, comprising:
providing the substrate with a plurality of first patterned structures and an underlying layer, the plurality of patterned structures having at least a first pitch;
forming an organic layer over the plurality of first patterned structures;
forming a plurality of organic spacers from said organic layer by performing a first spacer etch process;
forming a second spacer layer over the organic spacers;
forming a plurality of second spacers from said second spacer layer by performing a second spacer etch process; and
performing an organic spacer etch removal process,
wherein after performing the organic spacer etch removal process, the plurality of first patterned structures and the plurality of second spacers together forming a masking layer for generating a second pattern on the substrate, the second pattern having a second pitch, the second pitch being less than the first pitch.

2. The method of claim 1, the forming the organic layer and the forming the plurality of organic spacers being performed together.

3. The method of claim 2, the forming the organic layer and the forming the plurality of organic spacers being performed by a cyclic deposition etch process.

4. The method of claim 1, the plurality of organic spacers comprised of unsaturated hydrocarbons, pyrrole, or a carbon containing self-assembled monolayer.

5. The method of claim 1, the organic layer being formed via a plasma deposition process.

6. The method of claim 5, the organic layer comprised of unsaturated hydrocarbons or pyrrole.

7. The method of claim 1, the organic layer being formed via a spin on deposition process.

8. The method of claim 5, the organic layer comprised of carbon containing self-assembled monolayer.

9. A method for processing a substrate, comprising:
providing the substrate with a plurality of first patterned structures;
forming a plurality of organic spacers adjacent to the plurality of first patterned structures;
forming a plurality of second spacers adjacent to the plurality of organic spacers;
removing the plurality of organic spacers after forming the plurality of second spacers,
wherein after removing the plurality of organic spacers, the plurality of first patterned structures and the plurality of second spacers together forming a masking layer which has masking layer structures having a pitch that is 26 nm or less.

10. The method of claim 9, the plurality of organic spacers comprised unsaturated hydrocarbons, pyrrole, or a carbon containing self-assembled monolayer.

11. The method of claim 9, the first patterned structures comprised of silicon nitride.

12. The method of claim 9, the second spacers comprised of silicon oxide.

13. The method of claim 12, the first patterned structures comprised of silicon nitride.

14. The method of claim 9, the plurality of organic spacers being formed from an organic layer that is plasma deposited.

15. The method of claim 11, the plurality of organic spacers comprised of unsaturated hydrocarbons or pyrrole.

16. The method of claim 9, the plurality of organic spacers being formed from an organic layer that is formed via a spin on deposition process.

17. The method of claim 13, the plurality of organic spacers comprised of a carbon containing self-assembled monolayer.

18. A method for performing a self-aligned triple patterning pitch splitting masking process, comprising:
providing a plurality of mandrels on a substrate;
forming a plurality of organic spacers on the substrate;
forming a plurality of second spacers on the substrate, at least one of the plurality of organic spacers being located between at least one of the plurality of mandrels and at least one of the plurality of second spacers;
performing an organic spacer etch removal process, the plurality of mandrels and the plurality of second spacers remaining on the substrate after the organic spacer etch removal process; and
after the organic spacer etch removal process, utilizing the plurality of mandrels and the plurality of second spacers as a self-aligned triple patterning pitch splitting mask for masking at least one layer of the substrate during at least one subsequent etch step.

19. The method of claim 18, the plurality of organic spacers being formed by a cyclic deposition etch process.

20. The method of claim 18, the plurality of organic spacers being formed by a plasma deposition process.

21. The method of claim 18, the plurality of organic spacers being formed by a spin on deposition process.

22. The method of claim 18, the plurality of organic spacers comprised of unsaturated hydrocarbons, pyrrole, or a carbon containing self-assembled monolayer.

23. The method of claim 18, the self-aligned triple patterning pitch splitting mask having a pitch of 26 nm or less.

24. The method of claim 23, the plurality of mandrels comprised of silicon nitride.

25. The method of claim 23, the plurality of second spacers comprised of silicon oxide.

26. The method of claim 23, the plurality of mandrels comprised of silicon nitride and the plurality of second spacers comprised of silicon oxide.

27. The method of claim 23, the organic spacer comprised of unsaturated hydrocarbons, pyrrole, or a carbon containing self-assembled monolayer.
